(19) United States
(12) Patent Application Publication
(10) Pub. No.: US 2011/0193207 A1
(43) Pub. Date: Aug. 11, 2011

(54) LEAD FRAME FOR SEMICONDUCTOR DIE

(75) Inventors: Zhaojun Tian, Tianjin (CN); Qingchun He, Tianjin (CN); Qiang Liu, Tianjin (CN); Jie Yang, Tianjin (CN); Shufeng Zhao, Tianjin (CN)

(73) Assignee: FREESCALE SEMICONDUCTOR, INC, Austin, TX (US)

(21) Appl. No.: 13/004,031

(22) Filed: Jan. 11, 2011

(30) Foreign Application Priority Data
Feb. 9, 2010 (CN) 20100135577.5

(51) Int. Cl. H01L 23/495

(52) U.S. Cl. 257/676; 257/E23.031

(57) ABSTRACT

A lead frame for providing electrical interconnection to a semiconductor die has a generally rectangular flag area having first and second major surfaces and four sides. The flag area is sized and shaped to receive a semiconductor die on one of the first and second major surfaces. A first row of leads is located adjacent to a first one of the four sides of the flag area and a second row of leads is located adjacent to a second one of the four sides of the flag area, where the second one of the four sides is adjacent to the first one of the four sides. The remaining two sides do not have any adjacent leads.

### BACKGROUND OF THE INVENTION

The present invention relates to semiconductor packaging and, more particularly, to a lead frame for providing electrical interconnections to a semiconductor die.

Semiconductor dies include integrated circuits formed in Silicon that are usually packaged before being connected to other electronic devices or circuits. Such packaging often entails attaching and electrically connecting the die to a lead frame and then encapsulating the die and electrical connections with a mold compound. There are many types of leaded packages available, some with leads extending out of the sides of the mold compound and others with an array of pads on a bottom surface of the package, known as Quad Flat No lead (QFN) packages.

Integrated circuits have become more complex and at the same time, it has become possible to fabricate larger size dies with such more complex circuits. However, there is still a need for small packages that have more circuitry but do not require a much larger lead frame.

FIG. 1 shows one embodiment of a conventional lead frame 10 for a QFN type package. The lead frame 10 includes a flag area 12 for receiving a semiconductor die and leads 14 that are arranged on opposing sides of the flag area 12. (Some other lead frames have leads around all four sides of the flag area). More specifically, the lead frame 10 has six (6) leads, three on each of two opposing sides. The flag area 12 is 1.9 mm×2.5 mm. Thus, the flag area 12 can accommodate a square die measuring 1.9 mm×1.9 mm.

It would be advantageous to provide a lead frame with a larger flag area for a small package (e.g., six to eight leads).

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is an enlarged top plan view of a conventional lead frame for a small QFN package;

FIG. 2 is an enlarged top plan view of an embodiment of a lead frame for a small QFN package in accordance with an embodiment of the present invention; and

FIG. 3 is a top plan view of the lead frame of FIG. 2 including a semiconductor die attached to a flag area of the lead frame and wires electrically connecting the die to leads of the lead frame.

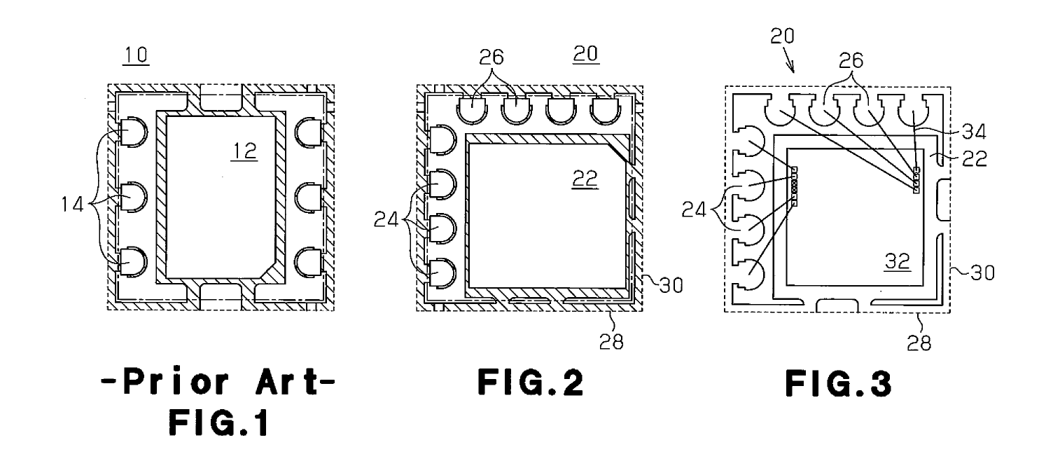

### DETAILED DESCRIPTION OF THE INVENTION

The present invention is directed to a lead frame for providing electrical interconnection to a semiconductor die. As lead frames generally are well known to those of skill in the art, the present invention is not described in any more detail then necessary so as to not obfuscate or distract from the teachings of the present invention. For example, the semiconductor die described herein can be any semiconductor material or combinations of materials, such as gallium arsenide, silicon germanium, silicon-on-insulator (SOI), silicon, monocrystalline silicon, the like, and combinations of the above.

In addition, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein. Moreover, unless stated otherwise, terms such as “first” and “second” are used to arbitrarily distinguish between the elements such terms describe. Thus, these terms are not necessarily intended to indicate temporal or other prioritization of such elements.

Further, terms defined using “a” or “an,” are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

In one embodiment, the present invention provides a lead frame for providing electrical interconnection to a semiconductor die. The lead frame includes a generally rectangular flag area having first and second major surfaces and four sides. The flag area is sized and shaped to receive a semiconductor die on one of the first and second major surfaces. A first row of leads is arranged adjacent to a first one of the four sides of the flag area, and a second row of leads is arranged adjacent to a second one of the four sides of the flag area, where the second one of the four sides is adjacent to the first one of the four sides. The remaining two sides of the flag area do not have any adjacent leads.

Referring now to FIG. 2, one embodiment of a lead frame 20 for providing electrical interconnection to a semiconductor die in accordance with the present invention is shown. The lead frame 20 includes a generally rectangular flag area 22 having first and second major surfaces and four sides. The flag area 22 is sized and shaped to receive a semiconductor die on one of the first and second major surfaces. Although not a requirement, in the embodiment shown, the flag area 22 is square and measures 2.4 mm×2.4 mm.

The lead frame 20 has a first row of leads 24 adjacent to a first one of the four sides of the flag area 22, and a second row of leads 26 adjacent to a second one of the four sides of the flag area 22, with the second one of the four sides being adjacent to the first one of the four sides. The remaining two sides 28 and 30 of the flag area 22 do not have any adjacent leads. That is, the present invention provides a lead frame with leads on adjacent sides, instead of leads on opposite sides, in order to increase the size of the flag area 22. In the embodiment shown, the first and second sides have the same number of leads adjacent thereto, which in this case is four (4). In other embodiments, the lead frame 20 may have fewer (e.g., three) or more (e.g., five or six) leads on adjacent sides.

As is known by those of skill in the art, the lead frame 20 may be formed from a sheet of copper foil (or other conductive metal, either bare or plated) with a process such as cutting, stamping or etching the foil sheet.

Referring now to FIG. 3, a top plan view of the lead frame 20 including a semiconductor die 32 attached to the flag area 22. The die 32 may be attached to the flag area 22 using a conventional die bonding adhesive. Bonding pads of the die 32 are electrically connected to respective ones of the leads 24 and 26 with wires 34. Such electrical connections may be made using commercially available wire bonding machines and the wires 34 may be made from a conductive metal, such as gold or copper.

By now it should be appreciated that there has been provided a lead frame for providing electrical interconnection to a semiconductor die. The lead frame allows for a larger die size to be attached to the flag area than a conventional small sized lead frame. Thus, larger die size products can be assembled with a small package size. Further, there is little material and process change required, thus cost is not increased. Although the invention is described herein with reference to specific embodiments, various modifications and changes can be made without departing from the scope of the present invention as set forth in the claims below, and the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

What is claimed is:

1. A lead frame for providing electrical interconnection to a semiconductor die, the lead frame comprising:
a generally rectangular flag area having first and second major surfaces and four sides, wherein the flag area is sized and shaped to receive a semiconductor die on one of the first and second major surfaces;
a first row of leads adjacent to a first one of the four sides of the flag area; and
a second row of leads adjacent to a second one of the four sides of the flag area, wherein the second one of the four sides is adjacent to the first one of the four sides, and wherein the remaining two sides of the flag area do not have any adjacent leads.

2. The lead frame of claim 1, wherein the flag area and the leads are formed from a sheet of copper foil.

3. The lead frame of claim 2, wherein the lead frame is formed by one of cutting, stamping or etching the foil sheet.

4. The lead frame of claim 1, wherein the first and second sides have the same number of leads adjacent thereto.

5. The lead frame of claim 4, wherein the first and second sides each have three leads adjacent thereto.

6. The lead frame of claim 5, wherein the first and second sides each of four leads adjacent thereto.

7. The lead frame of claim 1, wherein the flag area is square.

8. The lead frame of claim 7, wherein the flag area is 2.4 mm by 2.4 mm in size.

9. A lead frame for providing electrical interconnection to a semiconductor die, the lead frame comprising:
a generally rectangular flag area having first and second major surfaces and four sides, wherein the flag area is sized and shaped to receive a semiconductor die on one of the first and second major surfaces, and wherein the flag area is 2.4 mm by 2.4 mm in size;
a first row of leads adjacent to a first one of the four sides of the flag area, wherein the first row of leads includes three leads; and
a second row of leads adjacent to a second one of the four sides of the flag area, wherein the second one of the four sides is adjacent to the first one of the four sides, wherein the second row of leads includes three leads, and wherein the other two sides of the flag area do not have any adjacent leads.

10. The lead frame of claim of claim 9, wherein the flag area and the leads are formed from a sheet of copper foil by one of cutting, stamping or etching the foil sheet.
